(19) United States
(12) Patent Application Publication
(10) Pub. No.: US 2023/0178644 A1
(43) Pub. Date: Jun. 8, 2023

(54) RADIATION-HARD, TEMPERATURE TOLERANT, GAN HEMT DEVICES FOR RADIATION SENSING APPLICATIONS

(71) Applicant: National Research Council of Canada, Ottawa (CA)

(72) Inventors: Jean-Paul NOËL, Ottawa (CA); Ryan GRIFFIN, Ottawa (CA); Alexandre W. WALKER, Ottawa (CA)

(21) Appl. No.: 17/922,444

(22) PCT Filed: Apr. 27, 2021
(86) PCT No.: PCT/CA2021/050576

§ 371 Date: Oct. 31, 2022

Related U.S. Application Data
(60) Provisional application No. 63/113,165, filed on Nov. 12, 2020.
(60) Provisional application No. 63/018,623, filed on May 1, 2020.

(51) Int. Cl. H01L 29/778; H01L 29/20

(52) U.S. Cl. CPC H01L 29/7786; H01L 29/2003; H01L 29/7783

(57) ABSTRACT

A semiconductor high electron mobility transistor (HEMT)-based device configured to detect ionizing radiation, wherein the device comprises: a substrate; a nucleation layer formed on the substrate; a gallium nitride (GaN) buffer layer arranged on the nucleation layer; a GaN channel layer arranged on the GaN buffer layer; an aluminum nitride (A1N) spacer layer arranged on the GaN channel layer; a barrier layer arranged on the A1N spacer layer; a GaN cap layer arranged on the barrier layer; an electrically insulating silicon nitride (SiNx) passivation layer arranged on the GaN cap layer; a source, a drain and a gate, wherein the source and the drain are formed on the GaN cap layer; wherein charge carriers generated by the radiation in the underlying GaN layers are collected in the GaN channel layer and multiplied by impact ionization by a high electric field at the gate edge facing the drain contact.

### FIELD

Aspects of the disclosure relate to gallium nitride (GaN)-based devices for radiation-hard applications.

### BACKGROUND

Transistors are the basic building blocks of the electronics industry. Semiconductor substrates form the platform upon which transistors are constructed and so their properties dictate how those transistors operate.

Gallium nitride (GaN) semiconductors are now commonly found in optoelectronic and high-power devices, e.g., light-emitting diodes (LEDs) lasers and high electron mobility transistors (HEMTs). GaN is also gaining in popularity in high-power electronic devices at microwave frequencies due to a high breakdown electric field, good thermal conductivity, and the ability to operate at high temperature without significant loss of performance. GaN can also be used for detecting ionizing radiation under extreme radiation conditions due to its properties such as a wide band-gap (3.39 eV), large displacement energy (theoretical values averaging 10.96 eV for N and 4.50 eV for Ga), and high thermal stability (melting point: 2500° C.). Compared to narrower band-gap semiconductors such as silicon, GaN can operate at higher temperatures. Compared to other wide band-gap semiconductors, such as silicon carbide, GaN HEMTs exhibit higher electron mobility and better carrier transport properties, which is the reason RF microwave power amplifiers (up to 40 GHz) are designed and built with GaN HEMT technology. This accords GaN HEMTs with the necessary response time (~ 25 ps) for detection of the short-lived pulses of radiation-induced charge carriers.

Experiments, such as ATLAS currently being conducted at the LHC (Large Hadron Collider) at CERN, require components made from materials capable of withstanding very high radiation fluences. Some of the largest and most complex sensors ever devised to detect the particles generated and fragmented in collisions can be found in the LHC. A large portion of the sensing elements in the tracking detectors in the LHC are currently silicon-based, and their performance and lifespan degrades with increasing flux. The tracking detector components consist of silicon strip detectors, pixelated CMOS sensors, and low-gain avalanche detectors (LGADs). It is anticipated that in the upcoming upgrade to the LHC, the Future Circular Collider (FCC), the current silicon-based devices will be incapable of withstanding the flux that they will be exposed to. Accordingly, there is a need to develop the next generation of sensor technology fabricated with resilient materials that can withstand the increasingly harsh environments, to ensure the longest possible lifespan for the next generation sensor technology.

The use of GaN based sensors for radiation hard sensors has been investigated, with a focus on traditional diode structures, as would be found in silicon devices [1,2]. These sensors suffer some drawbacks, however, such as reduced sensitivity to weakly ionizing radiation, such that only alpha- particles have been detectable so far.

It is an object of the present disclosure to mitigate or obviate at least one of the above-mentioned disadvantages.

### SUMMARY

In one aspect, there is provided a semiconductor high electron mobility transistor (HEMT)-based device configured to detect ionizing radiation comprising high energy particles, wherein the device comprises:
a substrate;
a nucleation layer formed on the substrate;
a gallium nitride (GaN) buffer layer arranged on the nucleation layer;
a GaN channel layer arranged on the GaN buffer layer;
an aluminum nitride (A1N) spacer layer arranged on the GaN channel layer;
a barrier layer arranged on the AlN spacer layer;
a GaN cap layer arranged on the barrier layer;
an electrically insulating silicon nitride (SiNx) passivation layer arranged on the GaN cap layer;
a source, a drain and a gate, wherein the source and the drain are formed on the GaN cap layer with alloying to form ohmic contacts to the underlying GaN channel layer, and the gate is formed on the GaN cap layer without metallurgical alloying to render a Schottky junction;
wherein vias are fabricated through the SiNx passivation layer to allow connection of metal terminals of each of the source, drain and gate to the GaN semiconductor surface; and
wherein charge carriers generated by the radiation in the underlying GaN layers are collected in the GaN channel layer and multiplied by impact ionization by a high electric field at the gate edge facing the drain contact.

In another aspect, there is provided an ionizing radiation sensor comprising:
a gallium nitride (GaN) high electron mobility transistor (HEMT) for receiving high-energy particles, wherein the GaN atoms are ionized, directly or indirectly, to generate charge carriers as the radiation travels through the GaN HEMT; and
wherein the charge carriers are collected to generate a signal through application of lateral electric fields thereby collecting, and when suitably biased, amplifying the signal via impact ionization near the gate edge.

### BRIEF DESCRIPTION OF THE DRAWINGS

FIG. 1a shows a layer stack of a GaN HEMT device, in an exemplary embodiment

FIG. 1b shows the GaN HEMT device in terms of materials used to simulate the structure;

FIG. 1c shows electron concentration at equilibrium highlighting the transistor channel;

FIG. 1d shows an electric field at an operating point of interest as a radiation sensor;

FIG. 1e shows a scanning electron micrograph of the device;

FIG. 2a shows a simulated transfer curve of a GaN HEMT with a 20 V bias applied to the drain;

FIG. 2b shows an example of a transient from a MIP single event upset;

FIG. 3 shows a GEANT4 simulation of 500 keV beta-particles normally incident on a cubic millimeter of GaN; and

FIG. 4 shows a simulated single event upset generation profile in the GaN HEMT device.

### DETAILED DESCRIPTION

The following detailed description refers to the accompanying drawings. Wherever possible, the same reference numbers are used in the drawings and the following description to refer to the same or similar elements. While embodiments of the disclosure may be described, modifications, adaptations, and other implementations are possible. For example, substitutions, additions, or modifications may be made to the elements illustrated in the drawings, and the methods described herein may be modified by substituting, reordering, or adding stages to the disclosed methods. Accordingly, the following detailed description does not limit the disclosure. Instead, the proper scope of the disclosure is defined by the appended claims.

Moreover, it should be appreciated that the particular implementations shown and described herein are illustrative of the invention and are not intended to otherwise limit the scope of the present invention in any way. Indeed, for the sake of brevity, certain subcomponents of the individual operating components, and other functional aspects of the systems may not be described in detail herein. Furthermore, the connecting lines shown in the various figures contained herein are intended to represent exemplary functional relationships and/or physical couplings between the various elements. It should be noted that many alternative or additional functional relationships or physical connections may be present in a practical system.

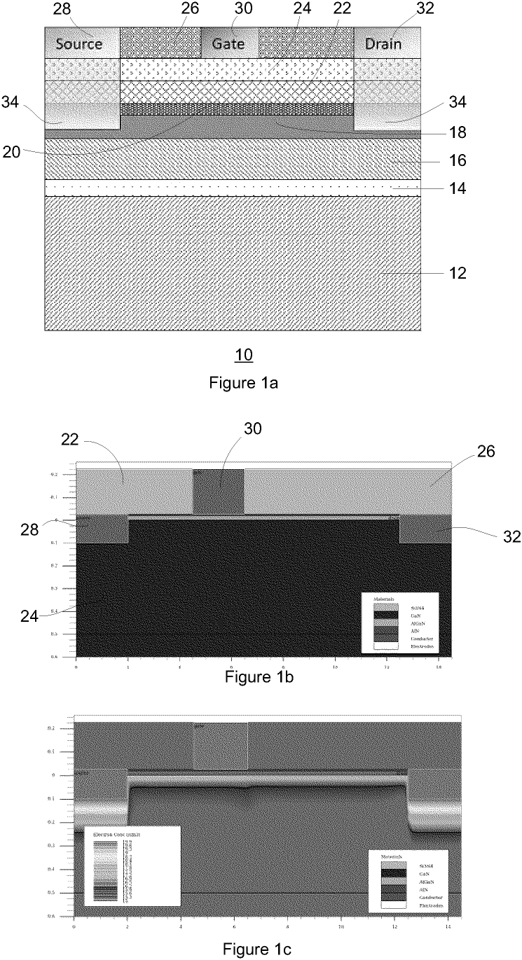

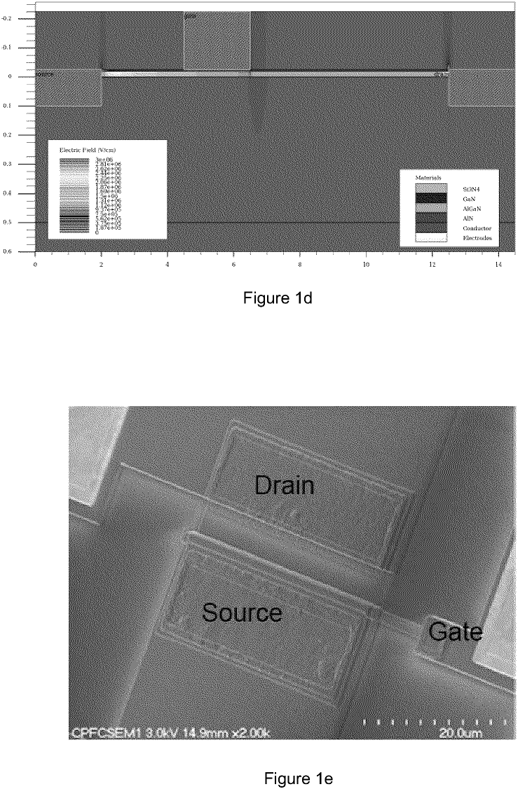

Referring to FIG. 1a, there is shown a schematic cross-section of a semiconductor body 10, such as a high electron mobility transistor (HEMT) structure, in one exemplary implementation. Semiconductor body 10 comprises a substrate, such as silicon carbide (SiC) substrate 12, nucleation layer 14 formed on SiC substrate 12, and a plurality of layers of semiconductor materials stacked thereupon. On top of nucleation layer 14 is gallium nitride (GaN) buffer layer 16 with GaN channel layer 18 thereon. Aluminum nitride (A1N) spacer layer 20 is arranged on GaN channel layer 18, and the barrier layer 22, such as aluminum gallium nitride (AlGaN) or aluminum nitride (InAlN), arranged on aluminum nitride (A1N) spacer 20 and GaN cap layer 24 overlies barrier layer 22, with silicon nitride (SiNx) passivation layer 26 arranged on GaN cap layer 24 in all areas where metal contacts are not present. Source 28, drain 32 and gate 30 are formed on GaN cap layer 24. Source 28 and drain 32 are formed on GaN cap layer 24 with alloying to form ohmic contacts to GaN channel layer 18, and gate 30 is formed on GaN cap layer 24 without metallurgical alloying to render a Schottky junction. Vias (openings) are fabricated through the SiNx passivation layer 26 to allow ohmic contacts 34 to be made to the GaN channel layer 18, and a Schottky gate 30 contact atop the GaN cap layer 24. As will be explained in greater detail below, charge carriers generated by the radiation in the underlying GaN buffer layer 16 are collected in GaN channel layer 18 and multiplied via impact ionization by a high electric field at the gate 30 edge facing the drain 32 contact. A planar metal contact on the device 10 back side is used as the 4th terminal for vertical field control to improve charge collection efficiency. Semiconductor gallium nitride (GaN) is known to be a radiation hard material, in part due to a large bandgap and a higher threshold for atomic defect generation compared to silicon, thus making it a very appealing sensor platform. The high electron mobility transistor (HEMT) structure 10 can be biased to generate a multiplication region adapted to achieve acceptable signal to noise ratio (SNR). In one implementation, voltage biasing and field configuration methods are employed to enhance sensitivity.

FIG. 1b shows a GaN HEMT device in terms of materials and geometry used to simulate structure 10. The geometrical configuration and the electrical behaviour of semiconductor devices 10 can be modelled using Technology Computed Aided Design (TCAD) simulation tools, such as those from Synopsys Inc., U.S.A., Silvaco Inc., U.S.A., and Crosslight Software Inc., U.S.A. Particularly relevant to the GaN/AlGaN technology is the polarization effects due to strain at the heterointerface leading to a high electron concentration in the channel forming the 2DEG. FIG. 1c shows a plot of electron concentration at equilibrium highlighting the transistor channel, while FIG. 1d shows an electric field in the GaN HEMT 10 cross-section highlighting the high field at the gate edge that leads to impact ionization; the source and drain contacts are assumed to be diffused through to the transistor channel, and the device is operating in “off” mode operation, i.e. V_{gate}<Vₜₕ and a V_{ds}=20 V. FIG. 1d also shows the gate contact above the channel, the basic dimensions of the device, and finally the carrier concentration in the transistor channel, which is shown to be high (>10²⁰ cm⁻³). Each layer of the simulation has specific material properties that are based on Silvaco Inc.’s default material library for GaN alloys including AlGaN. FIG. 1e shows a scanning electron micrograph of device 10.

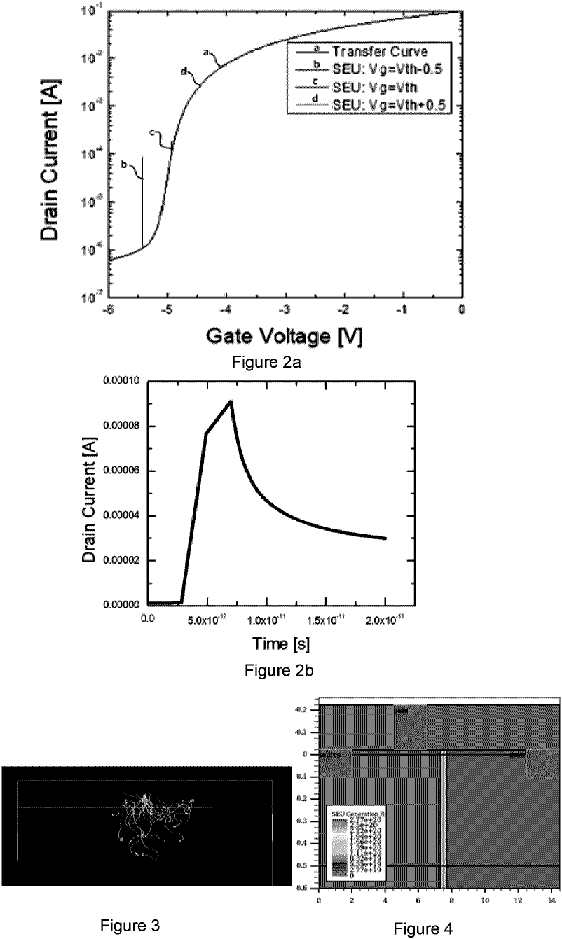

The Atlas semiconductor device module of Silvaco Inc. was used to simulate the electrical behaviour of a GaN HEMT device 10 and its response to a single event upset (SEU). FIG. 2a shows the simulated transfer curve of GaN HEMT device 10 with an operating bias of 20 V applied between drain 32 and source 28 while the gate 30 voltage is varied. This simulated transfer curve is in reasonable agreement with typical device experimental data from the National Research Council of Canada’s (NRC) standard GaN HEMT technology in terms of threshold voltage, the magnitude of the current in depletion-mode and when the gate 30 bias exceeds the threshold voltage (experimental data not shown).

FIG. 3 shows a simulation of 500 keV beta (β)-particle normally incident on a cubic millimeter GaN slab using a specialized software tool, GEANT4, a toolkit for the simulation of the passage of particles through matter. Note that the size of the simulated GaN volume is very large compared to the thickness of GaN HEMT device 10. The result of the GEANT4 simulation predicts approximately 170 electron-hole pairs generated per unit micrometer in the GaN material on average. This particular result is then used as an input parameter into the TCAD simulation in terms of the generation rate of the beta particle travelling through the GaN material. Note the dimensions of the GEANT4 simulation are orders of magnitude larger than the thickness of GaN HEMT device 10. It is therefore assumed to follow a linear path through the GaN HEMT device 10.

A single event upset may be simulated using the Silvaco tool set, which gives insight into the transient electrical behaviour of a high energy particle transferring energy into the semiconductor material. In a real-life scenario, this particle may induce displacement damage to the semiconductor material, which can (for sufficiently large energies), result in permanent damage to the material. However, modeling this effect requires more ab initio modeling such as Monte Carlo approaches. The focus is to study the electrical transient in order to determine whether GaN HEMT device 10 could directly detect ionizing radiation, such as a β-particle. It is important to note that indirect detection is also considered. An example of indirect detection includes neutron capture where atoms in the GaN lattice are converted to unstable isotopes which themselves decay via ionizing radiation, which is subsequently detected. Minimizing the effects of SEU on GaN HEMTs has been previously investigated [3], and the findings thereof are employed in developing the exemplary sensor of FIG. 1a. The input parameter into the simulation is essentially the path of the particle (entry and exit points and angle) and the amount of energy deposited as a generation rate per unit distance. A linear path is assumed with a small generation cross-section, as highlighted by FIG. 4 which shows the density of carriers generated by the β-particle passing between the gate 30 and drain 32.

According to this generation profile, the transient behaviour was simulated for various operating conditions of HEMT device 10. These are illustrated in FIG. 2a as vertical spikes on the transfer curve at different gate 30 biases, and FIG. 2b shows an example of a transient. The signal is easily detected when HEMT device 10 is “off”, i.e. for gate biases less than -5 V. The signal to noise ratio of this simulation (assuming the displacement damage is negligible in the GaN material) is ~100. When HEMT device 10 is “on”, i.e. for gate 30 biases greater than -5 V, the signal will be lost in the source-drain current. Additionally, a bias can be applied to a backside terminal to enhance collection of charges generated in the bulk by directing them vertically towards the channel. Enhanced collection can also be achieved via a built-in field developed using a doping gradient which directs charge to the channel for collection. A large electric field is generated at the gate 30 edge, as shown in FIG. 1d, and this field multiplies the charge ionized by the passing radiation that is collected from the bulk GaN and into the channel.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

Embodiments are described above with reference to block diagrams and/or operational illustrations of methods, systems. While the specification includes examples, the disclosure’s scope is indicated by the following claims. Furthermore, while the specification has been described in language specific to structural features and/or methodological acts, the claims are not limited to the features or acts described above. Rather, the specific features and acts described above are disclosed as example for embodiments.

### REFERENCES

[1] Jinhui Wang et al., Review of using gallium nitride for ionizing radiation detection, Appl. Phys. Rev 2. (2015)
[2] Stephen Pearton et al., Review of radiation damage in GaN-based materials and devices, J. Vacuum Sci. & Tech., (2013)
[3] A. Khachatrian, The Effect of the Gate Connected Field Plate on Single-Event Transients in AlGaN/GaN Schottky-Gate HEMTs, IEEE Trans. Nuc. Sci., (2019).

1. A semiconductor high electron mobility transistor (HEMT)-based device configured to detect ionizing radiation, wherein the device comprises:
a substrate;
a nucleation layer formed on the substrate; a gallium nitride (GaN) buffer layer arranged on the nucleation layer; a GaN channel layer arranged on the GaN buffer layer; an aluminum nitride (AIN) spacer layer arranged on the GaN channel layer;
a barrier layer arranged on the AIN spacer layer;
a GaN cap layer arranged on the barrier layer;
an electrically insulating silicon nitride (SiNx) passivation layer arranged on the GaN cap layer;
a source, a drain and a gate, wherein the source and the drain are formed on the GaN cap layer with alloying to form ohmic contacts to the underlying GaN channel layer, and the gate is formed on the GaN cap layer without metallurgical alloying to render a Schottky junction;
wherein vias are fabricated through the SiNx passivation layer to allow connection of metal terminals of each of the source, drain and gate to the GaN semiconductor surface; and
wherein charge carriers generated by the radiation in the underlying GaN layers are collected in the GaN channel layer and multiplied by impact ionization by a high electric field at the gate edge facing the drain contact.

2. The HEMT-based device of claim 1, comprising a designated multiplication region adapted to achieve acceptable signal to noise ratio (SNR).

3. The HEMT-based device of claim 1, comprising a multiplication region produced via voltage biasing, and adapted to achieve acceptable signal to noise ratio (SNR).

4. The HEMT-based device of claim 1, wherein a voltage bias is applied to the drain to enhance sensitivity of the HEMT-based device.

5. The HEMT-based device of claim 1, wherein a doping gradient is included in the GaN buffer to enhance sensitivity of the HEMT-based device.

6. The HEMT-based device of claim 1, wherein the bias is applied to a backside terminal to enhance collection of charges generated in the bulk by directing them vertically towards the channel.

7. The HEMT-based device of claim 1, wherein a varying voltage is applied to the gate to enhance sensitivity of the HEMT-based device.

8. The HEMT-based device of claim 1, wherein the ionizing radiation comprises beta-particles.

9. The HEMT-based device of claim 1, wherein the ionizing radiation comprises alpha-particles.

10. The HEMT-based device of claim 1, wherein the ionizing radiation is produced within the HEMT-based device or substrate.

11. The HEMT-based device of claim 1 , configured to detect the transient behaviour of the high energy particles transferring energy into the semiconductor material.

12. The HEMT-based device of claim 1, wherein the charge carriers generated by the ionizing radiation passing between the gate and drain follow a substantially linear path.

13. The HEMT-based device of claim 1, wherein gate-edge amplification of carriers is used to detect ionizing particles.

14. The HEMT-based device of claim 1, wherein the ionizing radiation is minimum ionizing particles.

15. The HEMT-based device of claim 1, wherein the barrier layer is aluminum gallium nitride (AlGaN).

16. The HEMT-based device of claim 1, wherein the barrier layer is indium aluminum nitride (InAIN).

17. The HEMT-based device of claim 1, wherein the substrate is at least one of silicon carbide (SiC), silicon, sapphire, gallium nitride, and other suitable material.

18. An ionizing radiation sensor comprising:
a gallium nitride (GaN) high electron mobility transistor (HEMT) for receiving high-energy particles, wherein the GaN atoms are ionized, directly or indirectly, to generate charge carriers as the radiation travels through the GaN HEMT; and
wherein the charge carriers are collected to generate a signal through application of lateral electric fields thereby collecting, and when suitably biased, amplifying the signal via impact ionization near the gate edge.

19. The sensor of claim 18, wherein the high-energy particles are beta-particles.

20. The sensor of claim 18, wherein the high-energy particles are alpha-particles.

21. The sensor of claim 18, wherein the lateral electric fields amplify the signal without the GaN HEMT undergoing breakdown.

22. The sensor of claim 18, comprising a multiplication region adapted to achieve an acceptable signal to noise ratio (SNR).
